(19) United States
(12) Patent Application Publication
(10) Pub. No.: US 2020/0026974 A1
(43) Pub. Date: Jan. 23, 2020

(54) SMART TAPE AND LOGISTICS SYSTEM USING THE SAME

(71) Applicant: WILLSUN INTERNATIONAL CO., LTD., Taichung City (TW)

(72) Inventor: Cheng-Hsin Chuang, Taichung City (TW)

(21) Appl. No.: 16/206,205

(22) Filed: Nov. 30, 2018

Related U.S. Application Data
(60) Provisional application No. 62/699,156, filed on Jul. 17, 2018.

(51) Int. Cl. G06K 19/07; H01L 23/498; H01L 23/00

(52) U.S. Cl. CPC G06K 19/0723; H01L 23/4985; H01L 2224/32225; H01L 23/564; H01L 24/32; H01L 23/49838

(57) ABSTRACT

A smart tape has a flexible substrate, chip, conductive glue, shielding layer and back glue layer. The chip is disposed above or below the flexible substrate. The conductive glue is electrically connected to the chip through the flexible substrate and has a specific pattern, so as to function as a sensing unit for sensing whether the smart tape has been peeled off. The shielding layer is disposed above the chip to protect the chip and prevent oxidation of the conductive glue. The back glue layer is disposed below the flexible substrate.

### CROSS-REFERENCE TO RELATED APPLICATION

This non-provisional application claims priority under 35 U.S.C. § 119(a) on Patent Application No. 62/699,156 filed in U.S. on Jul. 17, 2018, the entire contents of which are hereby incorporated by reference.

### FIELD OF THE INVENTION

The present disclosure relates to smart tapes and logistics systems using the same and, more particularly, to a smart tape and a logistics system using the same such that the smart tape can be easily peeled and adhered to an object and can sense the condition of goods being transported.

### BACKGROUND OF THE INVENTION

Conventional radio frequency (RF) sensing technology is sophisticated and widely applicable to various fields and scenarios. For example, a conventional e-tag includes an antenna, chip and tape. The antenna and chip are embedded in the tape and used to communicate with an external reading device, so as to achieve recipient verification and thus protect goods being transported against unauthorized collection or misappropriation. However, the conventional e-tag does not have any sensor required for sending the condition of the goods. As a result, the conventional e-tag can only protect the goods against fraudulent replacement or loss but cannot sense the condition of the goods or assist in investigating into the cause of any damage done to the goods and identifying the wrongdoer. For example, the goods are food and thus vulnerable when placed in warm or humid environments, which means that the food must be preserved at low temperature. However, the conventional e-tag is unable to sense and determine whether the food being transported is inappropriately preserved. As a result, the food rots in the course of transportation.

The conventional e-tag is capable of one-time impact sensing (hereinafter referred to as the impact sensing e-tag). During transportation of goods, if an impact overwhelms the impact sensing e-tag, the impact sensing e-tag will crack, indicating that the goods are damaged. However, to identify the wrongdoer who damaged the goods, it is necessary to inspect the impact sensing e-tag regularly to confirm whether the impact sensing e-tag has cracked; however, regular inspections are time-consuming and laborious.

### SUMMARY OF THE INVENTION

To overcome the aforesaid drawback of the prior art, an embodiment of the present disclosure provides a smart tape. The smart tape is capable of sensing to confirm the condition of goods quickly and assist in determining the cause of damage done to the goods and identifying the wrongdoer. The smart tape in the embodiment of the present disclosure is advantageously lightweight, thin and easy to adhere to an object.

In order to achieve the above and other objectives, the present disclosure provides a smart tape having a flexible substrate, chip, conductive glue, shielding layer and back glue layer. The chip is disposed above or below the flexible substrate. The conductive glue is electrically connected to the chip through the flexible substrate and has a specific pattern, so as to function as a sensing unit for sensing whether the smart tape has been peeled off. The shielding layer is disposed above the chip to protect the chip and prevent oxidation of the conductive glue. The back glue layer is disposed below the flexible substrate.

Optionally, in the embodiment of the present disclosure, the chip is disposed below the flexible substrate, and the smart tape further comprises an adhesive layer and an anisotropic conductive film. The adhesive layer is formed on the flexible substrate and a portion of back glue layer and has an opening. The adhesive layer prevents oxidation of the conductive glue. A portion of the conductive glue is exposed from the opening. The anisotropic conductive film is formed at the opening and provides a vertical conductive path and thus electrically connect to the conductive glue and chip. The conductive glue is formed on a portion of adhesive layer. The shielding layer covers the conductive glue and a portion of adhesive layer. The back glue layer is disposed below a portion of adhesive layer and on an outer side of the chip.

Optionally, in the embodiment of the present disclosure, the smart tape further comprises a releasing paper and a carrying substrate. The releasing paper is disposed below the chip and back glue layer. The carrying substrate is disposed above the shielding layer.

Optionally, in the embodiment of the present disclosure, the flexible substrate is made of polyimide, and the carrying substrate is made of polyethylene terephthalate (PET).

Optionally, in the embodiment of the present disclosure, the chip is disposed above the flexible substrate, and the conductive glue further comprises a conductive adhesive member. The conductive adhesive member allows the chip to be adhered to the flexible substrate and allow the chip to be electrically connected to the conductive glue through the conductive adhesive member. The shielding layer covers the chip, the conductive glue and the flexible substrate.

Optionally, in the embodiment of the present disclosure, the flexible substrate is made of polyimide.

Optionally, in the embodiment of the present disclosure, the chip is a microcontroller chip and comprises a communication unit, a read circuit, a memory and a control unit, wherein the control unit is electrically connected to the communication unit, read circuit, memory and conductive glue.

Optionally, in the embodiment of the present disclosure, the control unit sends a scanning signal to the conductive glue, and the conductive glue sends a sensing signal to the control unit.

In order to achieve at least one of the aforesaid objectives, the embodiment of the present disclosure provides a logistics system comprising the smart tape and the server. The smart tape is adhered to a goods or a package for the goods. The server is in communication connection with the smart tape to receive a plurality of data sent from the smart tape.

Optionally, in the embodiment of the present disclosure, the plurality of data is a plurality of data blocks forming a block bond.

In short, the smart tape provided in the embodiment of the present disclosure allows a user to quickly confirm the conditions of the goods and identify the wrongdoer soon whenever the goods are damaged. Furthermore, the logistics system equipped with the smart tape further turns data blocks sent from the smart tape into a block bond for storage to therefore prevent unauthorized persons from changing the data blocks fraudulently.

### BRIEF DESCRIPTION OF THE DRAWINGS

FIG. 1A is an exploded view of a smart tape according to the first embodiment of the present disclosure;

FIG. 1B is a perspective view of the smart tape according to the first embodiment of the present disclosure;

FIG. 2A is a schematic view of how to form the smart tape according to the second embodiment of the present disclosure;

FIG. 2B is a schematic view of how to form the smart tape according to the second embodiment of the present disclosure;

FIG. 2C is a schematic view of how to form the smart tape according to the second embodiment of the present disclosure;

FIG. 2D is a schematic view of how to form the smart tape according to the second embodiment of the present disclosure;

FIG. 2E is a schematic view of how to form the smart tape according to the second embodiment of the present disclosure;

FIG. 2F is a schematic view of how to form the smart tape according to the second embodiment of the present disclosure;

FIG. 2G is a schematic view of how to form the smart tape according to the second embodiment of the present disclosure;

FIG. 3 is a function block diagram of the circuit of the smart tape according to the first embodiment and the second embodiment of the present disclosure; and

FIG. 4 is a schematic view of a logistics system using the smart tape according to an embodiment of the present disclosure.

### DETAILED DESCRIPTION OF THE PREFERRED EMBODIMENTS

Objectives, features, and advantages of the present disclosure are hereunder illustrated with specific embodiments, depicted with drawings, and described below. The words “above” and “below” used in the embodiments are merely intended to describe relative positions. For example, object A is below object B, and object C is above object D. In practice, the opposite can be true, that is, object A is above object B, and object C is below object D.

An embodiment of the present disclosure provides a smart tape which is not only light and thin but is also easy to be peeled and adhered to an object. The smart tape has a chip mounted on a flexible substrate. The shielding layer is disposed above the chip. The back glue layer is disposed below or on an outer side of the chip. Owing to the back glue layer, the smart tape can be adhered to the goods or a package box (or a package bag). The smart tape has a sensing unit comprising conductive glue or any other type of sensing unit. The smart tape sends sensed data to a computer device or server through a communication unit of the chip automatically, so as to record the condition of the goods and thus reduce the time and efforts required for recording the condition of the goods manually. Hence, the smart tape in the embodiment of the present disclosure can quickly confirm the conditions of the goods and assist in investigating into the cause of any damage done to the goods and identifying the wrongdoer.

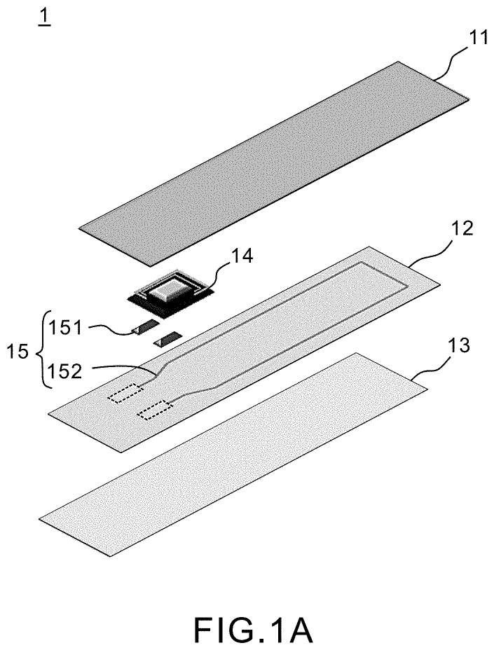

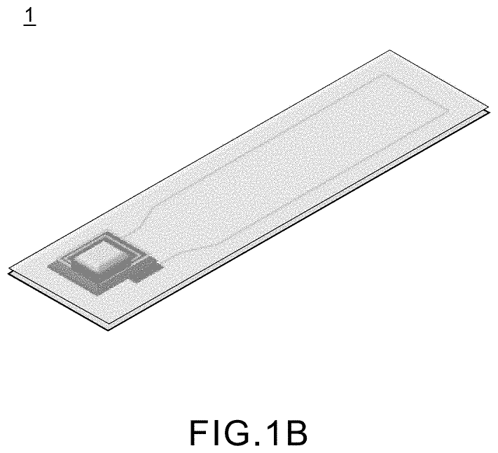

Referring to FIG. 1A and FIG. 1B, there is shown in FIG. 1A an exploded view of the smart tape according to the first embodiment of the present disclosure, and there is shown in FIG. 1B a perspective view of the smart tape according to the first embodiment of the present disclosure. The smart tape 1 comprises a shielding layer 11, a flexible substrate 12, a back glue layer 13, a chip 14, and a conductive glue 15. The conductive glue 15 comprises a conductive adhesive member 151 and a conductive glue member 152. The flexible substrate 12 is a plastic substrate and is made of polyimide, but the present disclosure is not limited thereto. The conductive adhesive member 151 is disposed at a position (i.e., indicated by a dashed line shown in FIG. 1A) defined on the flexible substrate 12. The conductive glue member 152 is disposed at a position defined on the flexible substrate 12. The conductive glue 15 is disposed at a position defined on the flexible substrate 12. The conductive adhesive member 151 is connected to the conductive glue member 152 so that both are electrically connected to each other. Furthermore, two ends of the conductive glue member 152 are connected to the conductive adhesive member 151 and thus the conductive glue member 152 is substantially n-shaped, but the present disclosure is not limited thereto. The conductive glue 15 functions as a sensing unit for sensing whether the smart tape 1 has been peeled off.

The chip 14 is adhered to the flexible substrate 12 through the conductive adhesive member 151. The chip 14 is electrically connected to the conductive glue 15. The shielding layer 11 is made of an insulating material and covers the flexible substrate 12, the chip 14 and the conductive glue 15. The shielding layer 11 not only protects the chip 14 and conductive glue 15 but also prevents any external air from affecting the chip 14 and conductive glue 15 to therefore achieve protection and insulation, and even prevents oxidation of the conductive glue 15. The back glue layer 13 is adhered to the flexible substrate 12 from below. A releasing paper (not shown in FIG. 1A and FIG. 1B) is disposed beneath the back glue layer 13. The back glue layer 13 enables the smart tape 1 to be adhered to goods or a package box (or a package bag) for the goods.

In the first embodiment, the chip 14 sends scanning signals to the conductive glue 15 regularly. If the smart tape 1 is not peeled off, sensing signals which the chip 14 receives from the conductive glue 15 are substantially equivalent to scanning signals. However, as soon as the smart tape 1 is peeled off, the sensing signals which the chip 14 receives from the conductive glue 15 are markedly different from the scanning signals. Hence, the conductive glue 15 functions as a sensing unit for sensing whether the smart tape 1 has been peeled off. As soon as the smart tape 1 is peeled off, the chip 14 sends the received sensing signals to an external computer device or server. Hence, the smart tape 1 in the first embodiment of the present disclosure can quickly confirm the conditions of the goods and assist in investigating into the cause of any damage done to the goods and identifying the wrongdoer. For instance, if the smart tape 1 is not peeled off at the recipient side, it will be likely that the goods are subjected to a great impact or are stolen or fraudulently collected.

Without compromising its general features, the chip 14 further comprises another sensing unit, such as a temperature sensing unit and a humidity sensing unit, for recording temperature and humidity sensed and sending temperature and humidity sensed to an external computer device or server. Hence, if the goods are food or medication, the smart tape can determine whether the food or medication is correctly preserved in the course of transportation. The other sensing unit is not only a temperature sensing unit or a humidity sensing unit, but is also a gravity sensing unit or a magnetism sensing unit. The conductive glue 15 is silver glue, carbon glue, copper glue, anisotropic conductive glue or the like, but the present disclosure is not limited thereto.

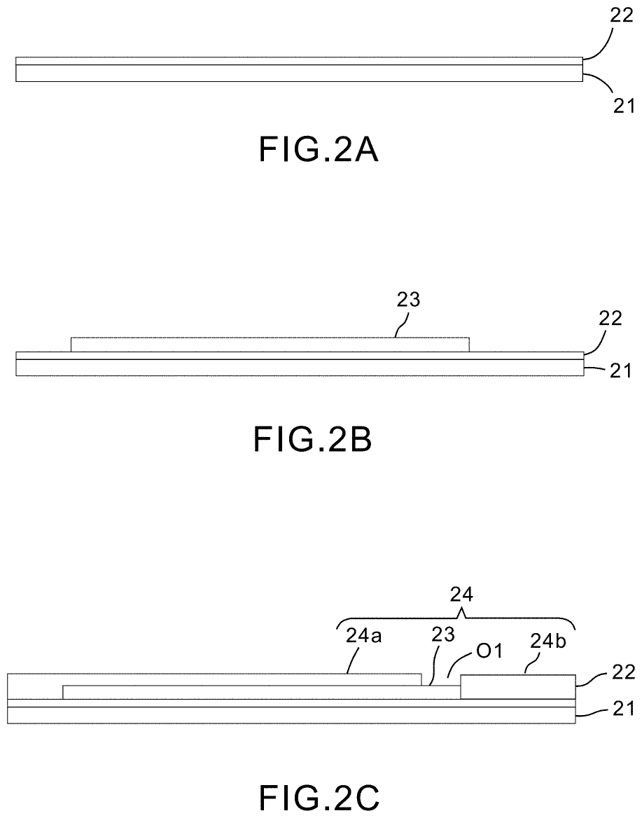

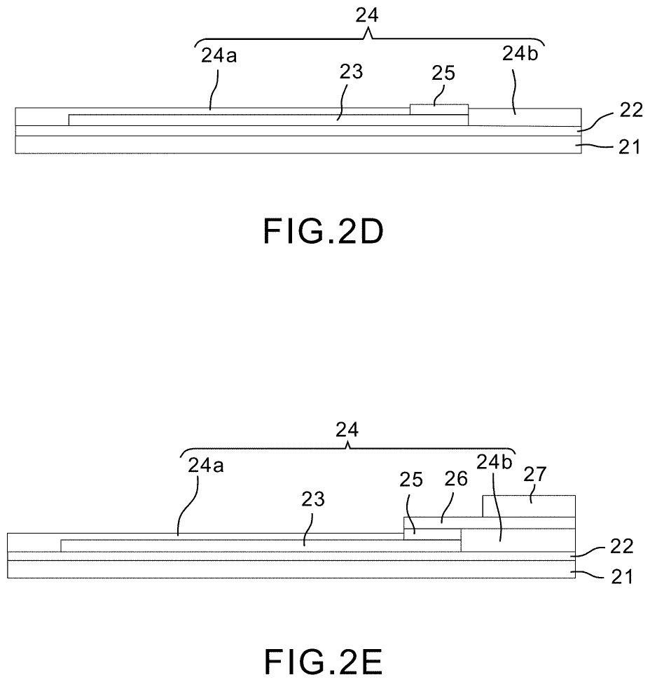

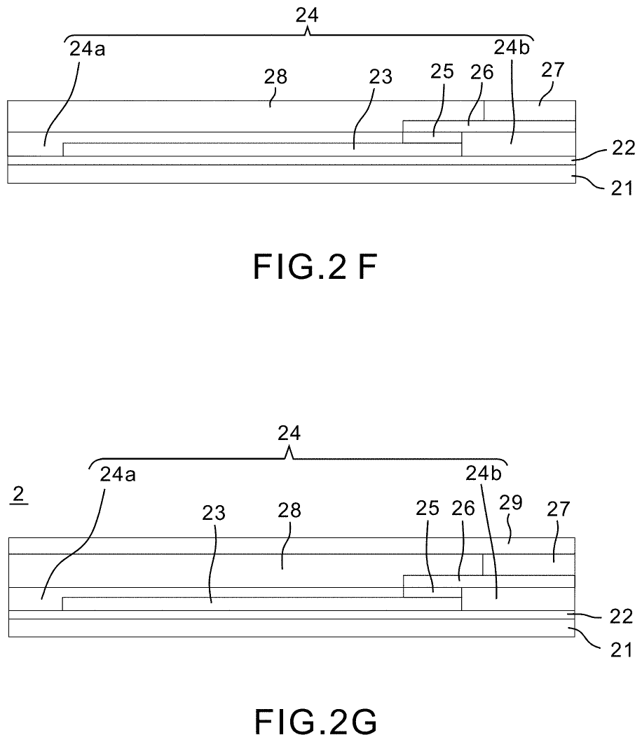

In addition to the smart tape of the first embodiment, the second embodiment of the present disclosure provides another smart tape. Referring to FIG. 2A˜FIG. 2G, FIG. 2A˜FIG. 2G are schematic views of formation of the smart tape according to the second embodiment of the present disclosure. Referring to FIG. 2G, a smart tape 2 comprises a carrying substrate 21, a shielding layer 22, a conductive glue 23, an adhesive layer 24 (comprising a first portion of adhesive layer 24a and a second portion of adhesive layer 24b), an anisotropic conductive film 25, a flexible substrate 26, a chip 27, a back glue layer 28 and a releasing paper 29. The releasing paper 29 can be peeled off to allow the smart tape 2 to be adhered to the goods or a package box (or a package bag) for the goods. Therefore, when the smart tape 2 can be adhered to the goods or a package box (or a package bag) for the goods, the smart tape 2 of FIG. 2G is upside down. In addition, upon delivery of the smart tape 2, the carrying substrate 21 can be removed such that the smart tape 2 becomes lightweight and thin. Hence, the carrying substrate 21 is solely useful to the manufacturing process of the smart tape 2. If the smart tape 2 need not be lightweight and thin, the carrying substrate 21 need not be removed. Alternatively, the carrying substrate 21 may be removed only after the smart tape 2 has been adhered to the goods or a package box (or a package bag) for the goods. The conductive glue 23 is silver glue, carbon glue, copper glue, anisotropic conductive glue or the like, but the present disclosure is not limited thereto.

In the second embodiment, the shielding layer 22 is disposed above the carrying substrate 21, wherein the carrying substrate 21 is flexible and is made of polyethylene terephthalate (PET), for example, but the present disclosure is not limited thereto. The shielding layer 22 not only protects the chip 27 but also prevents external air from affecting the chip 27 to therefore achieve protection and insulation, and even prevent oxidation of the conductive glue 23. The conductive glue 23 is disposed above a portion of the shielding layer 22. The conductive glue 23 functions as a sensing unit for sensing whether the smart tape 2 has been peeled off.

The adhesive layer 24 is formed on a portion of conductive glue 23 and a portion of the shielding layer 22. The adhesive layer 24 comprises a first portion of adhesive layer 24a and a second portion of adhesive layer 24b. An opening O1 is disposed between the first portion of adhesive layer 24a and the second portion of adhesive layer 24b to expose the conductive glue 23. The conductive glue 23 thus exposed functions as an electrode pin electrically connected to the chip. The adhesive layer 24 prevents oxidation of the conductive glue 23. The anisotropic conductive film 25 is formed at the opening O1 and disposed on the exposed conductive glue 23. The anisotropic conductive film 25 provides a vertical conductive path.

The flexible substrate 26 is formed on the second portion of adhesive layer 24b and the anisotropic conductive film 25. The chip 27 is formed on the flexible substrate 26. The flexible substrate 26 is made of polyimide (PI) film, but the present disclosure is not limited thereto. The flexible substrate 26 has a wiring for allowing the chip 27 to be electrically connected to the exposed conductive glue 23 through the anisotropic conductive film 25. In the second embodiment, the chip 27 is regarded as a signal processing end, whereas the conductive glue 23 is regarded as a sensing end (sensing unit), thereby allowing the flexible substrate 26 to not only carry the chip but also serve as a bridge of electrical connection.

The back glue layer 28 covers a portion of the flexible substrate 26 and the first portion of adhesive layer 24a. The upper surface of the back glue layer 28 is as high as the upper surface of the chip 27. Therefore, the back glue layer 28 is disposed on one side of the chip 27. The back glue layer 28 allows the smart tape 2 to be adhered to the goods or a package box (or a package bag) for the goods. The releasing paper 29 is disposed above the back glue layer 28 and the chip 27. To start using the smart tape 2, a user peels off the releasing paper 29 such that the back glue layer 28 can be adhered to the goods or a package box (or a package bag) for the goods. The manufacturing process produces a tape product comprising a plurality of smart tapes 2 shown in FIG. 2G wherein perforations are defined on the tape product comprising the plurality of smart tapes 2 to separate adjacent smart tapes 2, so as to render it easier for the user to cut the tape product.

The manufacturing process of the smart tape 2 is described below. Referring to FIG. 2A, the manufacturing process of the smart tape 2 entails providing the carrying substrate 21 whose upper surface has a shielding layer 22 capable of insulation. The shielding layer 22 is formed on the upper surface of the carrying substrate 21 by printing. Referring to FIG. 2B, afterward, the manufacturing process of the smart tape 2 entails forming a conductive glue 23 with a specific pattern on a portion of the shielding layer 22, wherein the conductive glue 23 is formed by printing and severs as a sensing unit. Referring to FIG. 2C, afterward, the manufacturing process of the smart tape 2 entails forming an adhesive layer 24 for covering the conductive glue 23 and a portion of the shielding layer 22 and then forming an opening O1 for separating the adhesive layer 24 into the first portion of adhesive layer 24a and the second portion of adhesive layer 24b and exposing a portion of conductive glue 23 for functioning as an electrode pin. Since the adhesive layer 24 covers a portion of conductive glue 23, it prevents oxidation of the conductive glue 23. Referring to FIG. 2D, afterward, the manufacturing process of the smart tape 2 entails forming the anisotropic conductive film 25 at the opening O1 to allow the anisotropic conductive film 25 to be electrically connected to the exposed conductive glue 23 and to provide a vertical conductive path (i.e., an electrical connection path in Z-direction) to the conductive glue 23.

Referring to FIG. 2E, afterward, the manufacturing process of the smart tape 2 entails forming the flexible substrate 26 for covering the second portion of adhesive layer 24b and the anisotropic conductive film 25 to allow the wiring on the flexible substrate 26 to electrically connect to the anisotropic conductive film 25 and form the exposed chip 27 on the flexible substrate 26. Since the wiring on the flexible substrate 26 electrically connects to the chip 27, signals of the chip 27 can be sent to the conductive glue 23, and signals of the conductive glue 23 can be sent to the chip 27. Likewise, the chip 27 can send scanning signals to the conductive glue 23, and the conductive glue 23 can send sensing signals to the chip 27, so as to sense whether the smart tape 2 has been peeled off. Referring to FIG. 2F, afterward, the manufacturing process of the smart tape 2 entails forming a back glue layer 28 for covering a portion of the flexible substrate 26 and the first portion of adhesive layer 24a, wherein the back glue layer 28 allows the smart tape 2 to be adhered to the goods or a package box (or a package bag) for the goods. Referring to FIG. 2G afterward, the manufacturing process of the smart tape 2 entails forming a releasing paper 29 for covering the chip 27 and the back glue layer 28, wherein the releasing paper 29 protects the back glue layer 28. To affix the smart tape 2 to the goods or a package box (or a package bag) for the goods, the user must peel off the releasing paper. After the smart tape 2 has been adhered to the goods or a package box (or a package bag) for the goods, the user can selectively remove the carrying substrate 21.

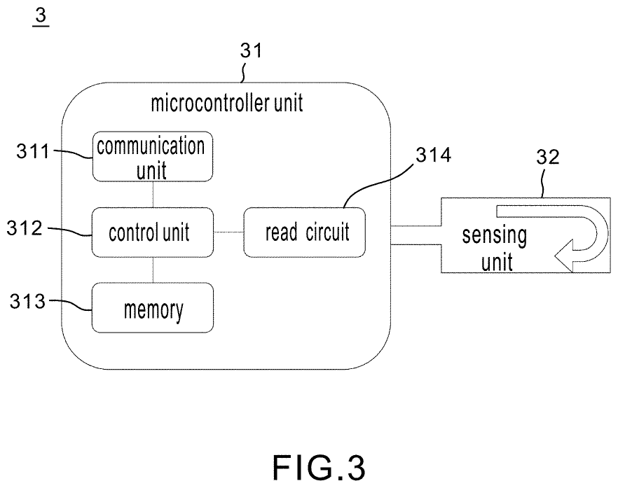

Referring to FIG. 3, there is shown in FIG. 3 a function block diagram of the circuit of the smart tape according to the first embodiment and the second embodiment of the present disclosure. A circuit 3 of the smart tape comprises a microcontroller unit 31 and a sensing unit 32. The microcontroller unit 31 is electrically connected to the sensing unit 32. The microcontroller unit 31 is implemented by the chip. The sensing unit 32 is implemented by the conductive glue with a specific pattern. The microcontroller unit 31 comprises a communication unit 311, a control unit 312, a memory 313 and a read circuit 314. The control unit 312 is electrically connected to the communication unit 311, the memory 313 and the read circuit 314. The control unit 312 is electrically connected to the sensing unit 32.

The control unit 312 controls the communication unit 311, the memory 313 and the read circuit 314. The communication unit 311 enables the circuit 3 of the smart tape to communicate with an external computer device and server and send data thereto. The memory 313 stores temporarily the sensing signals sent from the sensing unit 32. After beginning to communicate with the external computer device and server, the communication unit 311 sends the sensing signals to the external computer device and server. The read circuit 314 undergoes near-field communication with a computer device at a near end such that the computer device (for example, a cellular phone or any other handheld device) at the near end can access information about senders and recipients recorded by the read circuit 314. The control unit 312 sends the scanning signals to the sensing unit 32 to thereby obtain the sensing signals from the sensing unit 32.

The smart tape is applied to various fields, such as logistics system, packaging of drug cans or drug packs, counterfeit protection of electronic products, warehousing system, safekeeping of precious articles and home safety, but the present disclosure is not limited thereto.

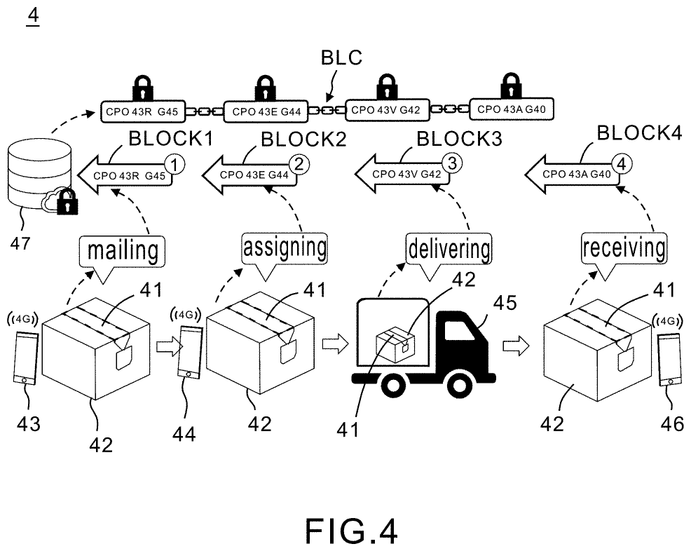

An embodiment of applying the smart tape to a logistics system is described below. Referring to FIG. 4, there is shown in FIG. 4 a schematic view of a logistics system using the smart tape according to an embodiment of the present disclosure. A logistics system 4 comprises a smart tape 41, a plurality of handheld devices 43˜46 and a server 47. At the mailing end, a sender affixes the smart tape 41 to a package box 42 for the goods, and the handheld device 43 writes information about the sender and recipient to the smart tape 41. The smart tape 41 sends resultant data block BLOCK1 to the server 47. At an assigning end, an assigner uses the handheld device 44 to obtain the sender and recipient information in the smart tape 41 and write the assignment information to the smart tape 41. The smart tape 41 sends resultant data block BLOCK2 to the server 47 and requests payment (if the sender has to bear a mailing fee). At a delivering end, a deliverer uses the handheld device 45 to obtain the sender and recipient information in the smart tape 41 and write the delivery information to the smart tape 41. The smart tape 41 sends resultant data block BLOCK3 to the server 47. At a receiving end, a receiver uses the handheld device 45 to obtain the sender and recipient information in the smart tape 41 and write the information to the smart tape 41. The smart tape 41 sends resultant data block BLOCK4 to the server 47. During the logistics process, the sensing unit of the smart tape 41 keeps detecting whether the smart tape 41 has been peeled off and sends related data to the server 47 upon affirmative detection. As mentioned before, the smart tape 41 further senses and sends humidity and temperature information to the server 47. Hence, given the smart tape 41, it is feasible to be informed of the condition of the goods in each step and identify the wrongdoer soon whenever the goods are damaged.

The data blocks BLOCK1˜BLOCK4 have their respective hash values calculated. The data block BLOCK2 uses the hash value of the data block BLOCK1 to point at the data block BLOCK1. The data block BLOCK3 uses the hash value of the data block BLOCK2 to point at the data block BLOCK2. The data block BLOCK4 uses the hash value of the data block BLOCK3 to point at the data block BLOCK3. Hence, the data blocks BLOCK1˜BLOCK4 form a block bond BLC. Therefore, it is feasible to effectively prevent unauthorized persons from changing the data blocks fraudulently. Although the aforesaid embodiment is exemplified by storing the block bond BLC in the server 47, but the present disclosure is not limited thereto. In a variant embodiment, the block bond BLC is stored in a plurality of computer devices and a plurality of servers to attain decentralization advantageously.

Therefore, the embodiment of the present disclosure provides a smart tape for sensing whether the smart tape has been peeled off and sending a sensing signal to an external computer device or server for storage. Hence, given the smart tape, it is feasible to be informed of the condition of the goods and identify the wrongdoer soon whenever the goods are damaged. In one of the embodiments of the present disclosure, the smart tape further senses humidity and temperature to thereby assess the condition of the goods (that is, whether the goods being transported is properly preserved). Furthermore, the smart tape is lightweight, thin and low-cost and thus has great market potential, not to mention that it is suitable for being introduced into a logistics system for usage. The server or computer device in the logistics system turns the data blocks sent from the smart tape into a block bond for storage, so as to effectively prevent unauthorized persons from changing the data blocks fraudulently.

The present disclosure is disclosed above by preferred embodiments. However, persons skilled in the art should understand that the preferred embodiments are illustrative of the present disclosure only, but shall not be interpreted as restrictive of the scope of the present disclosure. Hence, all equivalent modifications and replacements made to the aforesaid embodiments shall fall within the scope of the present disclosure. Accordingly, the legal protection for the present disclosure shall be defined by the appended claims.

What is claimed is:

1. A smart tape, comprising:
a flexible substrate;
a chip disposed above or below the flexible substrate;
a conductive glue electrically connected to the chip through the flexible substrate and having a specific pattern, so as to function as a sensing unit for sensing whether the smart tape has been peeled off;
a shielding layer disposed above the chip to protect the chip and prevent oxidation of the conductive glue; and
a back glue layer disposed below the flexible substrate.

2. The smart tape of claim 1, wherein the chip is disposed below the flexible substrate, and the smart tape further comprises:
an adhesive layer formed on the flexible substrate and a portion of the back glue layer and having an opening, the adhesive layer preventing oxidation of the conductive glue, wherein a portion of the conductive glue is exposed from the opening; and
an anisotropic conductive film formed at the opening to provide a vertical conductive path and thus electrically connect to the conductive glue and the chip, wherein the conductive glue is formed on a portion of the adhesive layer, and the shielding layer covers the conductive glue and a portion of the adhesive layer, wherein the back glue layer is disposed below a portion of the adhesive layer and on an outer side of the chip.

3. The smart tape of claim 2, further comprising:
a releasing paper disposed below the chip and the back glue layer; and
a carrying substrate disposed above the shielding layer.

4. The smart tape of claim 3, wherein the flexible substrate is made of polyimide, and the carrying substrate is made of polyethylene terephthalate (PET).

5. The smart tape of claim 1, wherein the chip is disposed above the flexible substrate, and the conductive glue further comprises a conductive adhesive member allows the chip to be adhered to the flexible substrate and allow the chip to be electrically connected to the conductive glue through the conductive adhesive member, wherein the shielding layer covers the chip, the conductive glue and the flexible substrate.

6. The smart tape of claim 5, wherein the flexible substrate is made of polyimide.

7. The smart tape of claim 1, wherein the chip is a microcontroller chip and comprises:
a communication unit;
a read circuit;
a memory; and
a control unit electrically connected to the communication unit, the read circuit, the memory and the conductive glue.

8. The smart tape of claim 7, wherein the control unit sends a scanning signal to the conductive glue, and the conductive glue sends a sensing signal to the control unit.

9. A logistics system, comprising:
the smart tape of claim 1, adhered to a goods or a package for the goods; and
a server in communication connection with the smart tape to receive a plurality of data sent from the smart tape.

10. The logistics system of claim 9, wherein the plurality of data is a plurality of data blocks forming a block bond.
